(19) United States
(12) Patent Application Publication
(10) Pub. No.: US 2009/0028352 A1
(43) Pub. Date: Jan. 29, 2009

(54) SIGNAL PROCESS FOR THE DERIVATION OF IMPROVED DTM DYNAMIC TINNITUS MITIGATION SOUND

(76) Inventor: Michael L. PETROFF, Marina Del Rey, CA (US)

Correspondence Address: LEVINE BAGADE HAN LLP, 2483 EAST BAYSHORE ROAD, SUITE 100, PALO ALTO, CA, 94303, US

(21) Appl. No.: 11/970,469

(22) Filed: Jan. 7, 2008

Related U.S. Application Data
(60) Provisional application No. 60/962,010, filed on Jul. 24, 2007.

(51) Int. Cl. H03G 3/00

(52) U.S. Cl. 381/61

(57) ABSTRACT

Systems and methods are disclosed for the derivation of improved DTM dynamic tinnitus mitigation sound formats. The system combines at least one recorded natural sound known to partially mask tinnitus with computer-generated sound that emulates such at least one natural sound and, in certain embodiments, further applies to at least one of the natural sound, computer-generated sound or combined sound at least one function of high frequency dynamic amplitude expansion, digital frequency shifting of high components to higher frequency ranges, selectable ones of a family of high frequency equalization curves, or band pass filtering. The resulting improved DTM sound exhibits a highly dynamic amplitude envelope and enhanced high frequency energy density, thereby providing superior tinnitus masking efficacy relative to prior art DTM and conventional masking sounds.

### CROSS-REFERENCE TO RELATED APPLICATIONS

This application claims priority to Provisional Application Ser. No. 60/962,010, filed Jul. 24, 2007, the content of which is incorporated by reference.

### FIELD OF THE INVENTION

The present invention relates to generation of tinnitus masking sound.

### BACKGROUND OF THE INVENTION

Tinnitus is a condition that causes a person to perceive noises in their ear when no external sound is present, generally due to an abnormal stimulus of a hearing nerve. The condition is frequently caused by exposure to excessively loud sound, a disease of the ear, trauma to the ear or a vascular disorder. Tinnitus often takes the form of a ringing sound, which may be intermittent or constant, varies from low to high pitch, and occurs usually in one ear or sometimes in both ears. Between 15 and 20 percent of adults have experienced some type of tinnitus, and 4 percent of those have suffered from serious symptoms. The most typical cause of the tinnitus is damage to the hearing nerve, and in middle age, the hearing nerve can be somewhat degenerated or damaged, and thereby, ringing in the ears may occur. Recently it has been noted that exposure to loud noises such as industrial noise, loud music, and the use of stereo headphones commonly induces tinnitus. Other causes vary from too much earwax to a serious disease.

As the causes of tinnitus are diverse, treatments are varied, including medication, surgery for conditions such as a brain tumor, vascular disease and muscle disease, and various masking sound methods that mask the perception of the tinnitus using speakers or an ear-worn device that produces a noise or other sounds generally louder than the tinnitus sound. Tinnitus treatments have been continuously studied to develop various tinnitus treatment devices. U.S. Pat. No. 6,047,074 entitled ‘Programmable hearing aid operable in a mode for tinnitus therapy’ discloses a programmable digital hearing aid including a signal converter, an amplifier, a digital signal processor, a memory, and acoustoelectrical input and output transducers. The programmable digital hearing aid is operable in a mode for tinnitus therapy using a tinnitus masking method. U.S. Pat. No. 6,682,472 entitled ‘Tinnitus rehabilitation device and method’ discloses a device and method that provide a predetermined masking algorithm for intermittent masking of the tinnitus wherein during peaks of the audio signal the tinnitus is completely obscured, whereas during troughs the perception of the tinnitus occasionally emerges, and which device and method may be employed in conjunction with a personal music player. U.S. Application 20060167335 entitled “Method and device for tinnitus therapy” discloses a method and device for tinnitus therapy. The method includes generating pure sounds, each having a predetermined frequency, within an audible range, and waiting for a user to press an input button when the user hears the pure sound. Then, the hearing characteristics of the user are interpreted in conjunction with equal loudness contours. From this interpretation, either a tinnitus masking method or a tinnitus retraining therapy is selected according to the hearing characteristics of the user.

Research conducted by M. J. Penner demonstrates that the minimum amplitude of an applied sound required to mask high frequency tinnitus is either substantially constant with frequency or follows the subject's hearing threshold curve. Conversely, research conducted by Dr. Jack Vernon demonstrates that the masking effectiveness of an applied sound is frequency dependent. This apparent discrepancy in research results may be explained by the time duration of subjectively reported masking following the application of the masking sound stimulus. Specifically, it has been found by the present inventor that a “short term distraction effect” exists whereby virtually any sound of adequate intensity results in short term auditory distraction, generally for 1 to 30 seconds, and a corresponding short-term masking of tinnitus. Many experimental tests of tinnitus masking, however, are conducted on the premise that successful masking may be assumed to have occurred immediately upon subjective indication of tinnitus suppression. It follows that such tests may not accurately predict the long-term masking properties of the corresponding sound stimuli, and that the above-described distraction effect may be capitalized upon in such a manner as to enhance tinnitus-masking efficacy.

The present inventor has developed and marketed products based on a signal process for the derivation of tinnitus masking sound formats, called “Dynamic Tinnitus Mitigation” or “DTM”, such sound formats providing clinically proven enhanced tinnitus masking efficacy relative to conventional tinnitus masking sounds. The signal process combines at least one recorded natural sound known to partially mask tinnitus, such as tile sound of flowing water, with computer-generated sound that does not emulate such at least one natural sound, wherein such combined sound produces a more dynamic amplitude envelope (greater ratios between minimum and maximum envelope amplitudes) than that of either the natural sound or the computer-generated sound, individually.

FIG. 1 is a block diagram of a prior art signal process for the derivation of conventional tinnitus masking sound formats, in which natural sound source NS1 provides signal S1 as input to high pass filter HPF1. HPF1 provides tinnitus masking sound output signal S2.

FIG. 2 is a block diagram of another prior art DTM signal process for the derivation of DTM dynamic tinnitus mitigation sound Formats, in which natural sound source NS1 provides signal S1 to a first input of mixer MIX1. Computer sound source CS1 provides signal S3 to a second input of MIX1. MIX1 provides DTM dynamic tinnitus mitigation sound output signal S4.

### SUMMARY OF THE INVENTION

Systems and methods are disclosed for the derivation of improved dynamic tinnitus mitigation (DTM) sound formats. The system combines at least one recorded natural sound known to partially mask tinnitus with computer-generated sound that emulates such at least one natural sound, wherein such combined sound produces a more dynamic amplitude envelope (greater ratios between minimum and maximum envelope amplitudes) and more effective tinnitus masking than that of either the natural sound or the computer-generated sound, individually, and in certain embodiments may further apply to at least one of the natural sound, computer-generated sound or combined sound at least one function of (1) high frequency dynamic amplitude expansion, (2) broad band dynamic amplitude expansion, (3) digital frequency shifting to higher frequency range(s), (4) selectable ones of a family of high frequency equalization curves, or (5) at least one band pass filter having a Q of at least 2 and preferably 10 to 100 at a center frequency in a high audio frequency range, typically between 1 kHz and 10 kHz, wherein such filter provides a peak response that is summed with a broad band response in such as manner as to provide at least one of (i), a substantially flat response curve substantially above such center frequency, or (ii), a substantially flat response curve substantially below such center frequency. In other embodiments, at least one of the above functions 1-5 may be repetitiously modulated in at least one of a short-time period between substantially 1 ms and substantially 100 ms, and a long-time period between substantially 1 second and substantially 1 hour, as a means to enhance long term masking efficacy.

In certain embodiments, the computer-generated sound emulates a natural flowing water sound (which is suitable for partial masking of tinnitus), and preferably is derived through a signal process comprising at least one step of (1) generating a broad band white noise signal, (2) processing the broad band white noise signal of step 1 by a high pass filter having a cut-off frequency of substantially 100 Hz (minimizing undesirable low frequency “roar” sound components) to create a filtered white noise signal, (3) generating a subsonic waveform signal in a frequency range below substantially 10 Hz, (4) amplitude modulating the filtered white noise signal of step 2 by the subsonic waveform signal of step 3 (emulating a sound of natural randomized water flow) to create a first amplitude modulated filtered white noise signal, (5) generating an ultra-low frequency random pulse signal, in which pulse intervals vary between substantially 100 MS and substantially 10 S and in which pulse durations vary between substantially 1 MS and substantially 100 MS, (6) amplitude modulating the first amplitude modulated filtered white noise signal of step 4 by the ultra-low frequency random pulse signal of step 5 (emulating a sound of natural water splattering) to create a second modulated filtered white noise signal, and (7) applying high frequency equalization, of substantially +1 to +10 dB at 1 to 4 kHz and substantially +2 to +20 db at 4 to 20 kHz, to the second modulated filtered white noise signal of step 6 (emulating a complete sound of natural flowing water) to create an equalized second modulated white noise signal. Equivalent variations, or alterations in sequence, of such steps do not alter the general principles comprised in the corresponding signal processing.

In other embodiments, the computer-generated sound emulates a natural cricket sound (which is suitable for partial masking of tinnitus), and preferably is derived through a signal process comprising at least one step of (1) capturing the peak-to-peak envelope waveform of live cricket sounds, (2) generating a harmonically rich composite signal comprising at least one component of (a) a sine wave, (b) a square wave, or (c) a saw-tooth wave, wherein each such component has substantially the same fundamental frequency in a region between substantially 1 Hz and substantially 10 kHz, (3) amplitude modulating the composite signal of step 2 by the envelope waveform of step 1 to create a modulated composite signal (emulating a sound of natural crickets), and (4) applying high frequency equalization, of substantially +1 to +6 dB at 2 to 4 kHz and substantially +2 to +12 dB at 5 to 10 kHz, to the modulated composite signal of step 3 to create an equalized modulated composite signal (emulating a complete sound of natural crickets). Equivalent variations, or alterations in sequence, of such steps do not alter the general principles comprised in the corresponding signal processing.

In another embodiment, a method for the derivation of improved dynamic tinnitus mitigation sound formats may comprise, generally, recording a natural sound known to partially mask tinnitus, rendering a computer generated sound that emulates the natural sound, and combining the natural sound with the computer-generated sound into a combined sound, wherein the combined sound produces a high dynamic amplitude envelope and a better tinnitus masking than that of either the natural sound or the computer-generated sound individually.

The computer generated sound and corresponding signal may be configured to may emulate, e.g., a natural flowing water sound, and are derived through signal processing. Such signal processing may comprise a broad band, substantially white noise signal which may be processed by a high pass filter having a cut-off frequency of about 100 Hz to create a filtered white noise signal. Moreover, the filtered white noise signal may be amplitude modulated by a subsonic waveform signal to create a first amplitude modulated filtered white noise signal. Generating the subsonic waveform signal may also comprise generating an ultra-low frequency random pulse signal, in which pulse intervals vary between substantially 100 ms and substantially 10 s and where pulse durations vary between substantially 1 ms and substantially 100 ms.

In a subsequent modulation process, the first amplitude modulated filtered white noise signal may be modulated by an ultra-low frequency random pulse signal to create a second modulated filtered white noise signal. The second modulated filtered white noise signal may be processed by high frequency equalization at substantially +1 to +6 dB at 2 to 4 kHz and substantially +2 to +12 db at 5 to 10 kHz to create an equalized second modulated white noise signal.

The computer generated sound and corresponding signal may alternatively be configured to emulate a natural cricket sound and are derived through signal processing. Such signal processing may comprise capturing the peak-to-peak envelope waveform of live cricket sounds; generating a harmonically rich composite signal comprising at least one component of a sine wave, a square wave or a saw-tooth wave, wherein each such component has substantially the same fundamental frequency in a region typically below substantially 10 Hz; amplitude modulating the composite signal may also comprise modulating by the envelope waveform to create a modulated composite signal, and applying high frequency equalization, of substantially +1 to +6 dB at 2 to 4 kHz and substantially +2 to +12 dB at 5 to 10 kHz, to the modulated composite signal to create an equalized modulated composite signal.

In deriving the improved dynamic tinnitus mitigation sound format, the method may also comprise a subsonic waveform signal in a frequency range below substantially 10 Hz.

Moreover, the computer-generated sound may be configured to emulate a natural cricket sound, and is derived through a signal process comprising capturing a peak-to-peak envelope waveform of live cricket sounds, generating a composite signal comprising at least one component of (i) a sine wave, (ii) a square wave, or (iii) a saw-tooth wave, wherein each component has substantially a predetermined fundamental frequency in a region between substantially 1 Hz and substantially 10 kHz, and modulating the composite signal by the envelope waveform.

Additionally, the recorded natural sound may be processed by at least one function of (a) high frequency dynamic amplitude expansion, (b) broad band dynamic amplitude expansion, (c) digital frequency shifting to higher frequency range(s), (d) selectable ones of a family of high frequency equalization curves, (e) at least one band pass filter having a Q of at least 2 and having a center frequency in a high audio frequency range, the filter providing a peak response that is summed with a broad band response The filter provides at least one of (i) a substantially flat response curve substantially above the center frequency, or (ii) a substantially flat response curve substantially below the center frequency. Moreover, at least one of the functions is repetitiously modulated in at least one of a short time period between substantially 1 ms and substantially 100 ms, and a long time period between substantially 1 second and 1 hour.

Furthermore, the computer-generated sound may be processed by at least one function of: (a) high frequency dynamic amplitude expansion, (b) broad band dynamic amplitude expansion, (c) digital frequency shifting to higher frequency range(s), (d) selectable ones of a family of high frequency equalization curves, (e) at least one band pass filter having a Q of at least 2 and having a center frequency in a high audio frequency range, such filter providing a peak response that is summed with a broad band response such as to provide at least one of, (i) a substantially flat response curve substantially above the center frequency, or (ii) a substantially flat response curve substantially below the center frequency. Additionally, the filter may provide at least one of: (i) a substantially flat response curve substantially above the center frequency, or (ii) a substantially flat response curve substantially below the center frequency.

Specific parameters for any step of the above signal processes may be altered, one or more steps may be excluded, additional steps may be added, and/or the type of emulated sound may be varied, in each case, although having a corresponding effect on the character of the sound, the principles of the present invention relating to computer-generation of emulated natural sounds remain substantially the same. Typically, such signal processes are performed using sophisticated MIDI audio recording software packages, such as Pro Tools and the like.

Advantages of the above exemplary system may include one or more of the following. The resulting improved tinnitus masking sound exhibits a highly dynamic amplitude envelope and enhanced high frequency impulse intensity, which has been demonstrated to provide superior tinnitus masking efficacy relative to prior art masking sounds. The resulting DTM sound provides dynamic (changing) formats of sound that gently distract hearing attention from tinnitus, as opposed to strictly masking over the tinnitus. DTM dynamic sound provides fundamental advantages over conventional non-dynamic sound and often suppresses tinnitus symptoms with one-third of the applied volume level previously required, resulting in a substantially more comfortable and enjoyable sound treatment of tinnitus symptoms.

### BRIEF DESCRIPTION OF THE DRAWINGS

FIG. 1 is a block diagram of a prior art signal process for the derivation of conventional tinnitus masking sound formats.

FIG. 2 is a block diagram of another prior art DTM signal process for the derivation of dynamic tinnitus mitigation (DTM) sound formats.

FIG. 3 is a block diagram of an improved DTM signal process of the preferred embodiment of the present invention for the derivation of improved DTM dynamic tinnitus mitigation sound formats.

FIG. 4 is a block diagram of a first alternative improved DTM signal process of the present invention for the derivation of improved DTM dynamic tinnitus mitigation sound formats.

FIG. 5 is a block diagram of a second alternative improved DTM signal process of the present invention for the derivation of improved DTM dynamic tinnitus mitigation sound formats.

FIG. 6 is a block diagram of a simplified improved DTM signal process of the present invention for the derivation of improved DTM tinnitus masking sound formats.

FIG. 7 is a block diagram of a first example set of signal processes that derive a computer generated sound source of the present invention, as illustrated in FIGS. 3, 4, 5 and 6.

FIG. 8 is a block diagram of a second example set of signal processes that derive a computer generated sound source of the present invention, as illustrated in FIGS. 3, 4, 5 and 6.

### DETAILED DESCRIPTION OF THE DRAWINGS

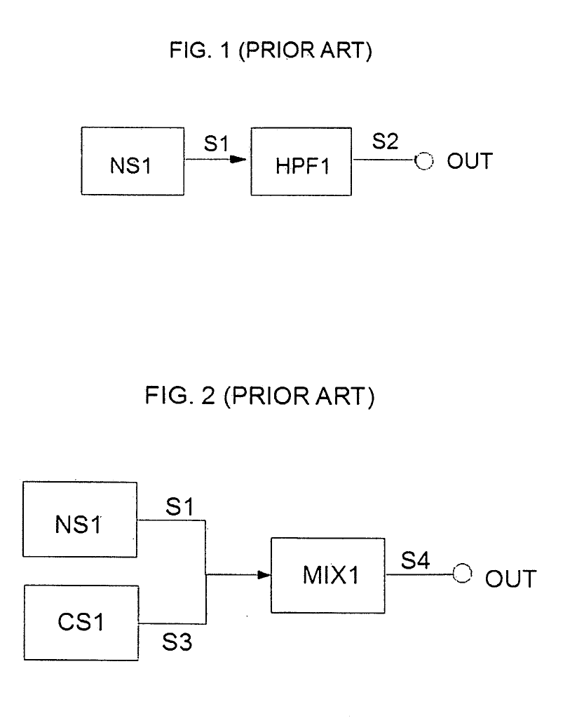

FIG. 1 is a block diagram of a prior art signal process for the derivation of conventional tinnitus masking sound formats, in which natural sound source NS1 provides signal S1 applied as input to high pass filter HPF1. HPF1 provides tinnitus masking sound output signal S2.

FIG. 2 is a block diagram of a prior art DTM signal process for the derivation of DTM dynamic tinnitus mitigation sound formats, in which natural sound source NS1 provides signal S1 applied to a first input of mixer MIX1. Computer sound source CS provides signal S3 applied to a second input of MIX1. MIX1 provides DTM dynamic tinnitus mitigation sound output signal S4.

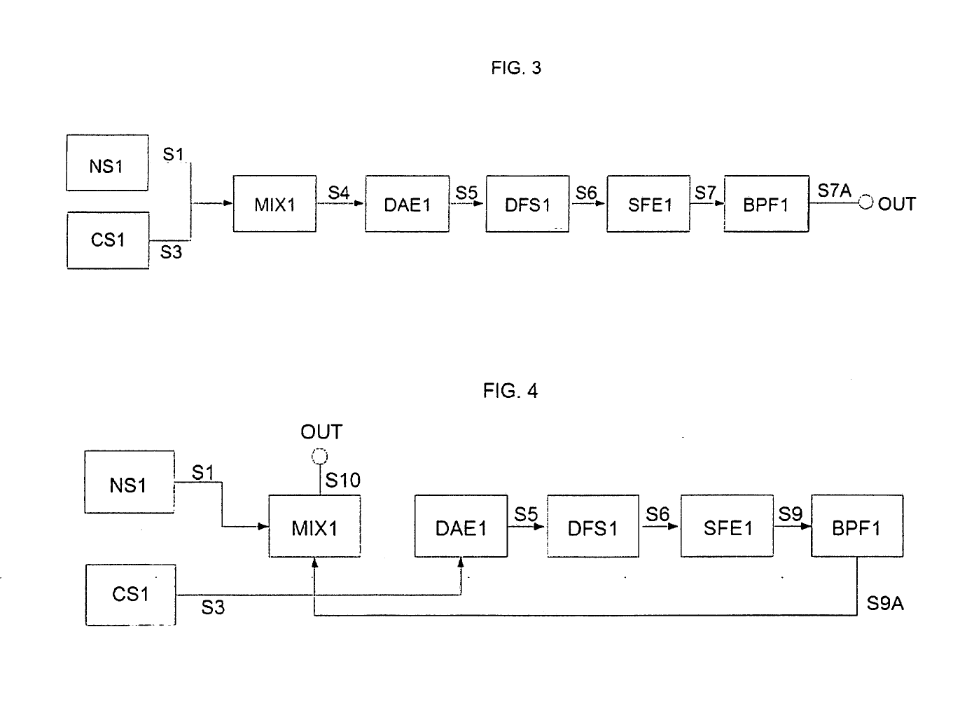

FIG. 3 is a block diagram of an improved DTM signal process of the preferred embodiment of the present invention for the derivation of improved DTM tinnitus masking sound formats, in which natural sound source NS1 provides signal S1 applied to a first input of mixer MIX1. Computer sound source CS1 (which emulates the sound of natural sound source NS1) provides signal S3 applied to a second input of MIX1. MIX1 provides signal S4 applied as input to dynamic amplitude expander DAE1. DAE1 provides signal S5 applied as input to digital frequency shifter DFS1. DFS1 provides signal S6 applied as input to selectable high frequency equalizer SFE1. SFE1 provides signal S7 applied as input to band pass filter BPF1. BPF1 provides improved DTM tinnitus masking sound output signal S7A.

FIG. 4 is a block diagram of a first alternative improved DTM signal process of the present invention for the derivation of improved DTM dynamic tinnitus mitigation sound formats, in which natural sound source NS1 provides signal S1 applied to a first input of mixer MIX1. Computer sound source CS1 (which emulates the sound of natural sound source NS1) provides signal S3 applied as input to digital frequency DAE1. DAE1 provides signal S5 applied as input to digital frequency shifter DFS1. DFS1 provides signal S6 applied as input to selectable high frequency equalizer SFE1. SFE1 provides signal S9 applied as input to band pass filter BPF1. BPF1 provides signal S9A applied to a second input of MIX1. MIX1 provides second improved DTM tinnitus masking sound output signal S10.

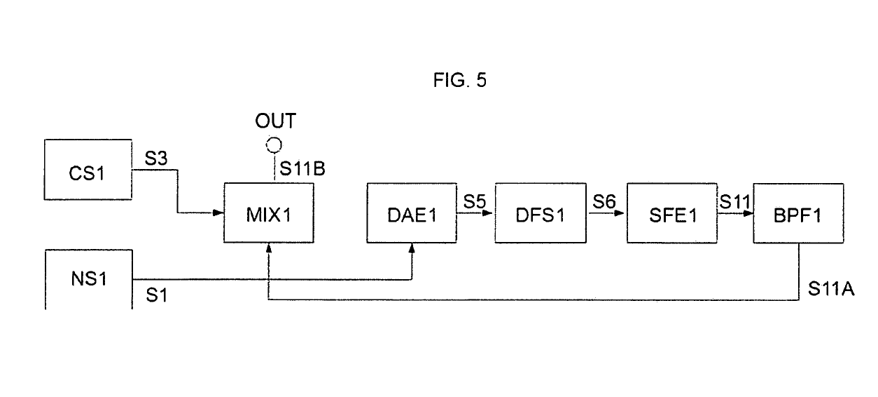

FIG. 5 is a block diagram of a second alternative improved DTM signal process of the present invention for the derivation of improved DTM dynamic tinnitus mitigation sound formats, in which computer sound source CS1 (which emulates the sound of natural sound source NS1) provides signal S3 applied to a first input of mixer MIX1. Natural sound source NS1 provides signal S1 applied as input to digital frequency DAE1. DAE1 provides signal S5 applied as input to digital frequency shifter DFS1. DFS1 provides signal S6 applied as input to selectable high frequency equalizer SFE1. SFE1 provides signal S11 applied as input to band pass filter BPF1. BPF1 provides signal S11A to a second input of MIX1. MIX1 provides second improved DTM tinnitus masking sound output signal S11B.

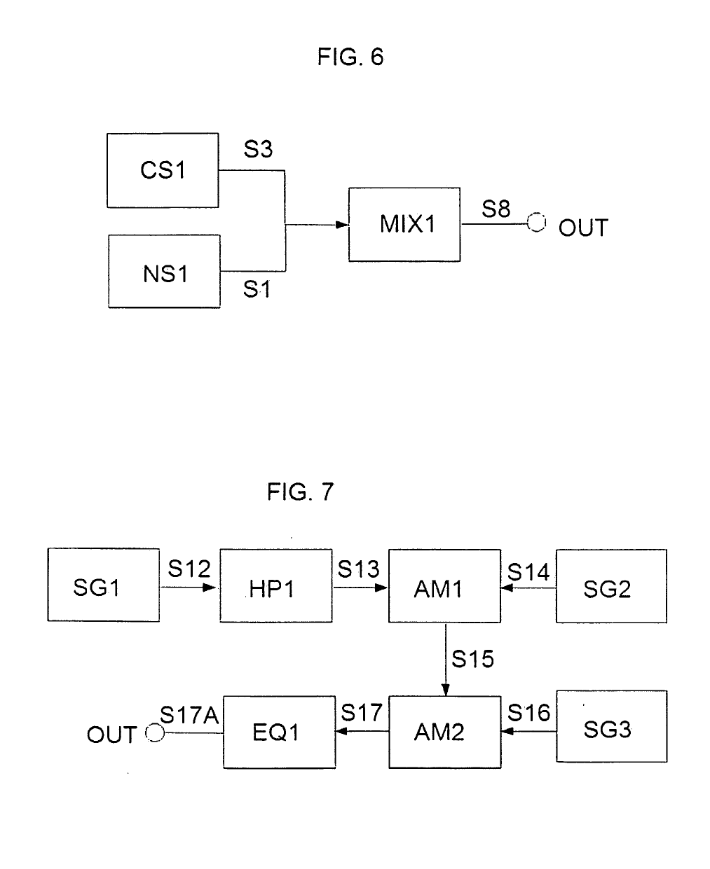

FIG. 6 is a block diagram of a simplified improved DTM signal process of the present invention for the derivation of improved DTM tinnitus masking sound formats, in which natural sound source NS1 provides signal S1 applied to a first input of mixer MIX1. Computer sound source CS1 (which emulates the sound of natural sound source NS1) provides signal S3 applied to a second input of MIX1. MIX1 provides improved DTM output signal S8.

FIG. 7 is a block diagram of a first example set of signal processes that derive a computer generated sound source of the present invention, as illustrated in FIGS. 3, 4, 5 and 6, such sound source emulating a natural water sound. Broadband white noise signal generator SG1 provides as output signal S12. S12 is applied as input to high pass filter HP1, having a cut-off frequency of substantially 100 Hz, and providing as output filtered white noise signal S13. Subsonic waveform signal generator SG2, which generates waveforms in a frequency range below substantially 5 Hz, provides as output subsonic waveform signal S14. S13 is applied to a signal input of first amplitude modulator AM1, and S14 is applied to a control input of AM1. AM1 provides as output first modulated filtered white noise signal S15, which emulates a sound of randomized water flow. Ultra-low frequency random pulse signal generator SG3, having pulse intervals that vary between substantially 100 MS and substantially 10 S and pulse durations that vary between substantially 1 MS and 100 MS, and provides random pulse output signal S16. Signal S15 is applied to a signal input of second amplitude modulator AM2, and S16 is applied to a control input of AM2. AM2 provides as output second modulated filtered white noise signal S17, which emulates a sound of natural water splattering. S17 is applied to high frequency equalizer EQ1, which introduces substantially +1 to +6 dB at 2 to 4 kHz and substantially +2 to +12 db at 5 to 10 kHz, and provides signal processed output signal S17A, which emulates a complete sound of natural flowing water. Astronomically

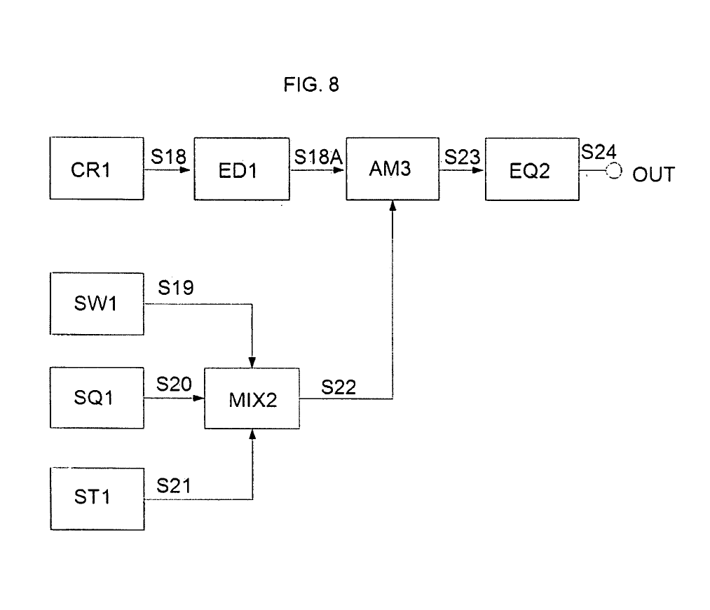

FIG. 8 is a block diagram of a second example set of signal processes that derive a computer generated sound source of the present invention, as illustrated in FIGS. 3, 4, 5 and 6, such sound source emulating a natural cricket sound. Live cricket recording source CR1 provides signal S18. S18 is applied-to envelope detector ED1, providing as output envelope signal S18A. Sine wave generator SW1 provides as output sine wave signal S19, square wave generator SQ1 provides as output square wave signal S20, and sawtooth wave generator ST1 provides as output sawtooth wave signal S21, wherein each such generator operates at substantially the same fundamental frequency typically in a region between 1 kHz and 10 kHz. Mixer MIX2 sums S19, S20 and S21, and provides as output harmonically rich composite signal S22. S22 is applied to a signal input of amplitude modulator AM3, and S18A is applied to a control input of AM3. AM3 provides as output modulated composite signal S23, which emulates a sound of natural crickets. S23 is applied as input to high frequency equalizer EQ2, which introduces substantially +1 to +6 dB at 2 to 4 kHz and substantially +2 to +12 dB at 5 to 10 kHz, and provides signal processed output signal S24, which emulates a complete sound of natural crickets.

The principles and features of the present invention will become further apparent from the following descriptions considered in conjunction with the accompanying drawings, in which designated letters and numbers correspond to like designated letters and numbers in the remaining drawings.

What is claimed is:

1. A method for the derivation of improved dynamic tinnitus mitigation sound formats, said system combining at least one recorded natural sound known to partially mask tinnitus with computer-generated sound that emulates such at least one natural sound, wherein such combined sound produces a more dynamic amplitude envelope and more effective tinnitus masking than that of either the natural sound or the computer-generated sound, individually.

2. The method of claim 1 in which at least one of the natural sound, computer-generated sound, or combined sound is processed by at least one function of;
a. high frequency dynamic amplitude expansion,
b. broad band dynamic amplitude expansion,
c. digital frequency shifting to higher frequency range(s),
d. selectable ones of a family of high frequency equalization curves, or
e. at least one band pass filter having a Q of at least 2 and having a center frequency in a high audio frequency range, such filter providing a peak response that is summed with a broad band response such as to provide at least one of,
i. a substantially flat response curve substantially above the center frequency, or
ii. a substantially flat response curve substantially below the center frequency.

3. The method of claim 2 in which at least one of the functions is repetitiously modulated in at least one of a short time period between substantially 1 ms and substantially 100 ms, and a long time period between substantially 1 second and substantially 1 hour.

4. The method of claim 1 in which the natural sound constitutes a natural flowing water sound and the computer-generated sound emulates such natural flowing water sound.

5. The method of claim 4 in which the computer-generated sound emulates the natural water sound and is derived through a signal process comprising at least one step of;
a. generating a broad band white noise signal,
b. processing the broad band white noise signal of step (a) by a high pass filter having a cut-off frequency of substantially 100 Hz to create a filtered white noise signal,
c. generating a subsonic waveform signal in a frequency range below substantially 5 Hz,
d. amplitude modulating the filtered white noise signal-of step (b) by the subsonic waveform signal to create a first amplitude modulated filtered white noise signal,
e. generating an ultra-low frequency random pulse signal, in which pulse intervals vary between substantially 100 MS and substantially 10 S and in which pulse durations vary between substantially 1 MS and substantially 100 MS,
f. amplitude modulating the first amplitude modulated filtered white noise signal of step (d) by the ultra-low frequency random pulse signal of step (e) to create a second modulated filtered white noise signal, and
g. applying high frequency equalization, of substantially +1 to +6 dB at 2 to 4 kHz and substantially +2 to +12 db at 5 to 10 kHz, to the second modulated filtered white noise signal of step (I) to create an equalized second modulated white noise signal.

6. The method of claim 1 in which the natural sound constitutes a natural cricket sound and the computer-generated sound emulates such natural cricket sound.

7. The method of claim 6 in which the computer-generated sound emulates the natural cricket sound and is derived through a signal process comprising at least one step of;
a. capturing the peak-to-peak envelope waveform of live cricket sounds,
b. generating a composite signal comprising at least one component of;
i. a sine wave,
ii. a square wave, or
iii. a sawtooth wave, wherein each such component has substantially the same fundamental frequency in a region between substantially 1 Hz and substantially 10 kHz,
c. amplitude modulating the composite signal of step (b) by the envelope waveform of step (a) to create a modulated composite signal, and
d. applying high frequency equalization, of substantially +1 to +6 dB at 2 to 4 kHz and substantially +2 to +12 dB at 5 to 10 kHz, to the modulated composite signal of step (c) to create an equalized modulated composite signal.

8. A method for the derivation of improved dynamic tinnitus mitigation sound formats, comprising:
recording a natural sound known to partially mask tinnitus;
rendering a computer generated sound that emulates the natural sound; and
combining the natural sound with the computer-generated sound into a combined sound, wherein the combined sound produces a high dynamic amplitude envelope and a better tinnitus masking than that of either the natural sound or the computer-generated sound individually.

9. The method of claim 8, wherein the computer-generated sound emulates a natural flowing water sound.

10. The method of claim 8, comprising deriving the computer-generated sound through signal processing.

11. The method of claim 8, comprising generating a broad band white noise signal.

12. The method of claim 11, comprising processing the broad band white noise signal with a high pass filter having a cut-off frequency of about 100 Hz to create a filtered white noise signal.

13. The method of claim 12, comprising amplitude modulating the filtered white noise signal by the subsonic waveform signal to create a first amplitude modulated filtered white noise signal.

14. The method of claim 13, comprising generating a subsonic waveform signal in a frequency range below substantially 10 Hz.

15. The method of claim 8, comprising generating an ultra-low frequency random pulse signal, in which pulse intervals vary between substantially 100 ms and substantially 10 s and where pulse durations vary between substantially 1 ms and substantially 100 ms.

16. The method of claim 15, comprising amplitude modulating the first amplitude modulated filtered white noise signal by the ultra-low frequency random pulse signal to create a second modulated filtered white noise signal.

17. The method of claim 15, comprising applying high frequency equalization at substantially +1 to +6 dB at 2 to 4 kHz and substantially +2 to +12 db at 5 to 10 kHz to the second modulated filtered white noise signal to create an equalized second modulated white noise signal.

18. The method of claim 8, wherein the computer-generated sound emulates a natural cricket sound, and is derived through a signal process comprising capturing a peak-to-peak envelope waveform of live cricket sounds.

19. The method of claim 17, comprising generating a composite signal comprising at least one component of;
i. a sine wave,
ii. a square wave, or
iii. a saw-tooth wave,
wherein each component has substantially a predetermined fundamental frequency in a region between substantially 1 Hz and substantially 10 kHz.

20. The method of claim 8, comprising amplitude modulating the composite signal by the envelope waveform to create a modulated composite signal.

21. The method of claim 17, comprising applying high frequency equalization, of substantially +1 to +6 dB at 2 to 4 kHz and substantially +2 to +12 dB at 5 to 10 kHz, to the modulated composite signal to create an equalized modulated composite signal.

22. The method of claim 8, wherein the natural sound is processed by at least one function of:
a. high frequency dynamic amplitude expansion,
b. broad band dynamic amplitude expansion,
c. digital frequency shifting to higher frequency range(s),
d. selectable ones of a family of high frequency equalization curves,
e. at least one band pass filter having a Q of at least 2 and having a center frequency in a high audio frequency range, the filter providing a peak response that is summed with a broad band response.

23. The method of claim 22, wherein the filter provides at least one of:
i. a substantially flat response curve substantially above the center frequency, or
ii. a substantially flat response curve substantially below the center frequency.

24. The method of claim 22, in which at least one of the functions is repetitiously modulated in at least one of a short time period between substantially 1 ms and substantially 100 ms, and a long time period between substantially 1 second and 1 hour.

25. The method of claim 8, wherein the computer-generated sound is processed by at least one function of:
a. high frequency dynamic amplitude expansion,
b. broad band dynamic amplitude expansion,
c. digital frequency shifting to higher frequency range(s),
d. selectable ones of a family of high frequency equalization curves,
e. at least one band pass filter having a Q of at least 2 and having a center frequency in a high audio frequency range, such filter providing a peak response that is summed with a broad band response.

26. The method of claim 25, wherein the filter provides at least one of:
i. a substantially flat response curve substantially above the center frequency, or
ii. a substantially flat response curve substantially below the center frequency.

27. The method of claim 25, in which at least one of the functions is repetitiously modulated in at least one of a short time period between substantially 1 ms and substantially 100 ms, and a long time period between substantially 1 second and 1 hour.

28. The method of claim 8, wherein the combined sound is processed by at least one function of:
a. high frequency dynamic amplitude expansion,
b. broad band dynamic amplitude expansion,
c. digital frequency shifting to higher frequency range(s),
d. selectable ones of a family of high frequency equalization curves, or
e. at least one band pass filter having a Q of at least 2 and having a center frequency in a high audio frequency range, the filter providing a peak response that is summed with a broad band response.

29. The method of claim 28, wherein the filter provides at least one of:
i. a substantially flat response curve substantially above the center frequency, or
ii. a substantially flat response curve substantially below the center frequency.

30. The method of claim 28, wherein at least one of the functions is repetitiously modulated in at least one of a short time period between substantially 1 ms and substantially 100 ms, and a long time period between substantially 1 second and 1 hour.
